(19) United States
(12) Patent Application Publication
(10) Pub. No.: US 2016/0139198 A1
(43) Pub. Date: May 19, 2016

(54) APPARATUS FOR TESTING ELECTRONIC DEVICES

(71) Applicant: Samsung Electronics Co., Ltd., Suwon-si (KR)

(72) Inventors: Bo-Seong Park, Asan-si (KR); Joo-In Song, Cheonan-si (KR); Min-Woo Kim, Cheonan-si (KR); Hye-ju Kim, Asan-si (KR); Chang-Ho Lee, Asan-si (KR); Jong-Hwan Lim, Asan-si (KR)

(21) Appl. No.: 14/920,252

(22) Filed: Oct. 22, 2015

(30) Foreign Application Priority Data
Nov. 19, 2014 (KR) 10-2014-0161502

(51) Int. Cl. G01R 31/28; F24F 7/08

(52) U.S. Cl. CPC G01R 31/2874; G01R 31/2862; F24F 7/08

(57) ABSTRACT

An apparatus for testing electronic devices may include a test chamber, a heating unit, a cooling unit and a controller. The test chamber may include a plurality of slots configured to receive the electronic devices. The heating unit may heat the electronic devices in the slots. The cooling unit may individually cool the electronic devices in the slots. The controller may selectively control operations of the heating unit and the cooling unit in accordance with temperatures in the slots. Thus, the electronic devices may be provided with a uniform test temperature so that reliability of test results may be improved.

### CROSS-RELATED APPLICATION

This application claims priority under 35 USC §119 to Korean Patent Application No. 2014-161502, filed on Nov. 19, 2014 in the Korean Intellectual Property Office (KIPO), the contents of which are herein incorporated by reference in their entirety.

### BACKGROUND

1. Field

Exemplary embodiments relate to an apparatus for testing electronic devices. More particularly, exemplary embodiments relate to an apparatus for testing solid state drives (SSD).

2. Description of the Related Art

Generally, an apparatus for testing SSDs may include a test chamber, a heating unit and a cooling unit. The test chamber may include a plurality of slots configured to receive the SSDs. The heating and cooling units may heat and cool, respectively, the SSDs in the slots and each unit may heat or cool the SSDs simultaneously in the slots

Accurate test results may be obtained by testing the SSDs in the slots under substantially the same temperature. However, simultaneously heating and cooling the SSDs may not provide the SSDs in the slots with a uniform test temperature. Particularly, when different heats may be generated by the SSDs, uniform test temperature may not be provided to the SSDs in the slots by simultaneously heating and cooling the SSDs.

### SUMMARY

Exemplary embodiments in accordance with principles of inventive concepts include an apparatus for testing electronic devices that may be capable of providing the electronic devices with a uniform test temperature.

According to exemplary embodiments, there may be provided an apparatus for testing electronic devices. The apparatus may include a test chamber, a heating unit, a cooling unit and a controller. The test chamber may include a plurality of slots configured to receive the electronic devices. The heating unit may heat the electronic devices in the slots. The cooling unit may individually cool the electronic devices in the slots. The controller may selectively control operations of the heating unit and the cooling unit in accordance with temperatures in the slots.

In exemplary embodiments, the controller may include temperature sensors arranged in the slots to measure the temperatures in the slots.

In exemplary embodiments, the electronic devices may include solid state drives (SSD) including temperature sensors. The controller may selectively control the operations of the heating unit and the cooling unit in accordance with the temperatures in the slots measured by the temperature sensors of the SSDs.

In exemplary embodiments, the heating unit may include a heater, a heating block and a heating shutter. The heater may generate heat. The heating block may include heating passageways connected between the heater and the slots. The heating shutter may open/close the heating passageways by the controller.

In exemplary embodiments, the heating unit may further include a circulation duct connected between the heater and the slots to supply the heat in the slots to the heater.

In exemplary embodiments, the circulation duct may include an exhaust vent configured to discharge the heat to the outside of the test chamber. The heating unit may further include an exhausting member configured to selectively open/close the exhaust vent of the circulation duct by the controller to discharge the heat in the circulation duct to the outside.

In exemplary embodiments, the exhausting member may include an exhausting shutter configured to selectively open/close the exhaust vent of the circulation duct, and an actuator configured to operate the exhausting shutter by the controller.

In exemplary embodiments, the exhausting member may further include an exhaust hood connected to the exhaust vent of the circulation duct.

In exemplary embodiments, the heating unit may further include a fan arranged between the circulation duct and the heat to circulate the heat.

In exemplary embodiments, the heating unit may further include a safety sensor configured to selectively stop the heater by the controller.

In exemplary embodiments, the cooling unit may include a chiller configured to generate a cooling air, and nozzles arranged in the slots to inject the cooling air into the slots.

According to some exemplary embodiments, there may be provided an apparatus for testing electronic devices. The apparatus may include a test chamber, a heating unit, a cooling unit and a controller. The test chamber may include a plurality of slots configured to receive the solid state drives (SSD) including temperature sensors. The heating unit may individually heat the SSDs in the slots. The cooling unit may individually cool the SSDs in the slots. The controller may selectively control operations of the heating unit and the cooling unit in accordance with temperatures in the slots.

In exemplary embodiments, the heating unit may include a heater, a heating block, a heating shutter, a circulation duct, a fan and an exhausting member. The heater may generate heat. The heating block may include heating passageways connected between the heater and the slots. The heating shutter may open/close the heating passageways by the controller. The circulation duct may be connected between the heater and the slots to supply the heat in the slots to the heater. The fan may be arranged between the circulation duct and the heat to circulate the heat. The exhausting member may be configured to selectively open/close the exhaust vent of the circulation duct by the controller to discharge the heat in the circulation duct to the outside.

In exemplary embodiments, the exhausting member may include an exhausting shutter configured to selectively open/close the exhaust vent of the circulation duct, and an actuator configured to operate the exhausting shutter by the controller.

In exemplary embodiments, the cooling unit may include a chiller configured to generate a cooling air, and nozzles arranged in the slots to inject the cooling air into the slots.

According to exemplary embodiments, the heating unit and/or the cooling unit may individually heat and/or cool the electronic devices in the slots so that temperatures of the electronic devices may be individually controlled. Thus, the electronic devices may be provided with a uniform test temperature so that reliability of test results may be improved. Further, the circulation duct of the heating unit may rapidly provide the test temperature to the electronic devices. Furthermore, the nozzles may individually cool the slots so that efficiency for cooling the slots may be improved. As a result, a time for testing the electronic devices may be remarkably decreased. Particularly, when the electronic device may include the SSD, it may not be required to provide the apparatus with additional temperature sensors so that the apparatus may have a low price.

In exemplary embodiments in accordance with principles of inventive concepts, an apparatus for testing electronic devices includes a test chamber for receiving a rack; a rack including a plurality of slots, the slots configured to receive the electronic devices; a heating unit configured to heat the electronic devices in the slots; a cooling unit configured to individually cool the electronic devices in each of the slots; and a controller configured to control the heating unit and the cooling unit according to internal temperatures of each of the slots.

In exemplary embodiments in accordance with principles of inventive concepts, an apparatus for testing electronic devices includes a controller configured to control the heating and cooling units in response to temperatures measured by sensors included on electronic devices being tested.

In exemplary embodiments in accordance with principles of inventive concepts, an apparatus for testing electronic devices includes a controller configured to control the heating and cooling units wherein the electronic devices being tested are solid state drives.

In exemplary embodiments in accordance with principles of inventive concepts, an apparatus for testing electronic devices includes a heating unit includes a heater configured to heat; a heating block having heating passageways, the heating passageways configured to individually connect the heat with the slots; heating shutters configured to selectively open/close the heating passageways under control of the controller; a circulation duct connected between the heater and the slots to circulate the heat between the slots and the heater, the circulation duct having an exhaust vent configured to exhaust the heat to an environment the outside the apparatus; a fan arranged between the circulation duct and the heater to circulate the heat; and an exhausting member configured to selectively open/close the exhaust vent.

In exemplary embodiments in accordance with principles of inventive concepts, an apparatus for testing electronic devices includes a cooling unit that includes a chiller configured to generate cooling air; and a nozzle arranged in each of the slots to inject the cooling air into the slots.

### BRIEF DESCRIPTION OF THE DRAWINGS

Exemplary embodiments will be more clearly understood from the following detailed description taken in conjunction with the accompanying drawings. FIGS. 1 to 12 represent non-limiting, exemplary embodiments as described herein.

FIG. 1 is a perspective view illustrating an apparatus for testing electronic devices in accordance with exemplary embodiments;

FIG. 2 is an exploded perspective view illustrating a front side of a test chamber in the apparatus of FIG. 1;

FIGS. 3 and 4 are perspective views illustrating a structure in the test chamber in FIG. 2;

FIG. 5 is a cross-sectional view illustrating a heating unit and a cooling unit in the test chamber of FIG. 2;

FIG. 6 is a perspective view illustrating a rear side of the test chamber in FIG. 2;

FIG. 7 is a perspective view illustrating a structure in the test chamber of FIG. 6;

FIG. 8 is an enlarged cross-sectional view illustrating a heating shutter of the test chamber in FIG. 7;

FIGS. 9 and 10 are cross-sectional views illustrating operations of a circulation duct in FIG. 2;

FIG. 11 is an enlarged perspective view illustrating an exhausting member in FIG. 9; and

FIG. 12 is a cross-sectional view illustrating an apparatus for testing electronic devices in accordance with exemplary embodiments.

### DETAILED DESCRIPTION OF THE EMBODIMENTS

Various exemplary embodiments will be described more fully hereinafter with reference to the accompanying drawings, in which some exemplary embodiments are shown. Inventive concepts may, however, be embodied in many different forms and should not be construed as limited to the exemplary embodiments set forth herein. Rather, these exemplary embodiments are provided so that this disclosure will be thorough and complete, and will fully convey the scope of inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of inventive concepts.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

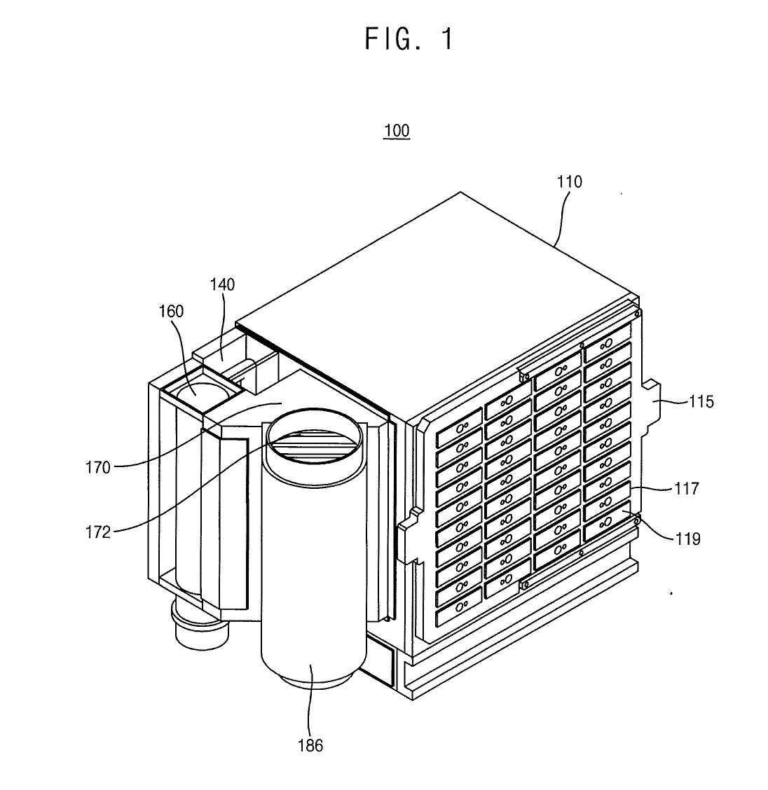

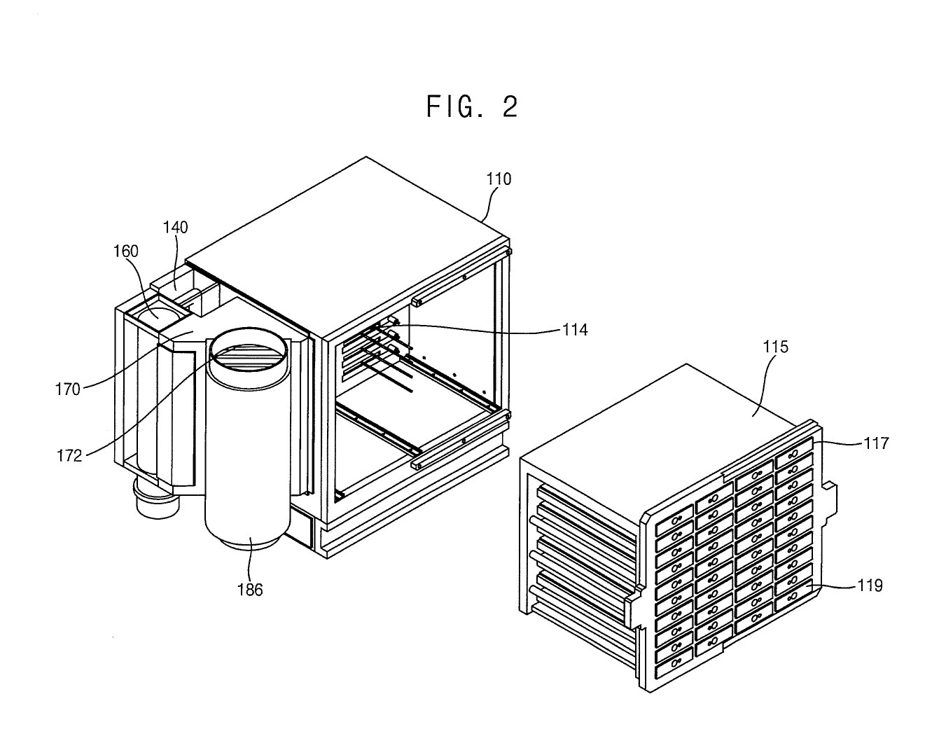

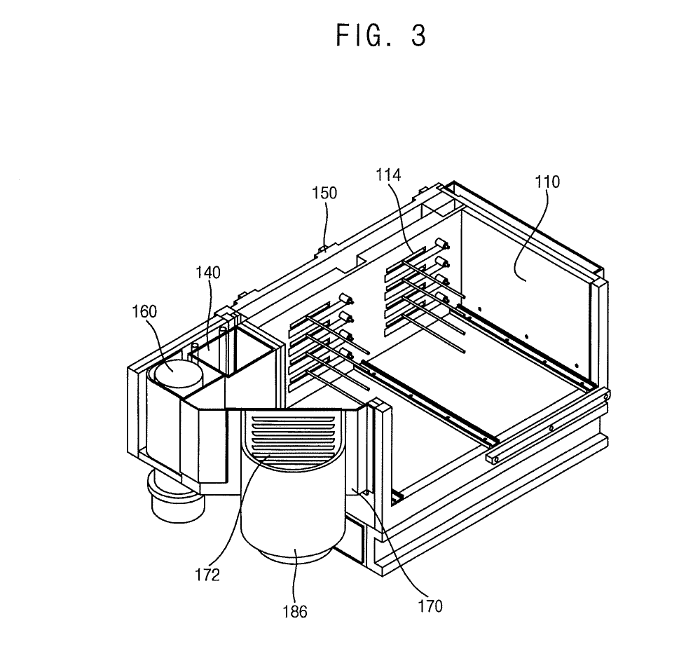

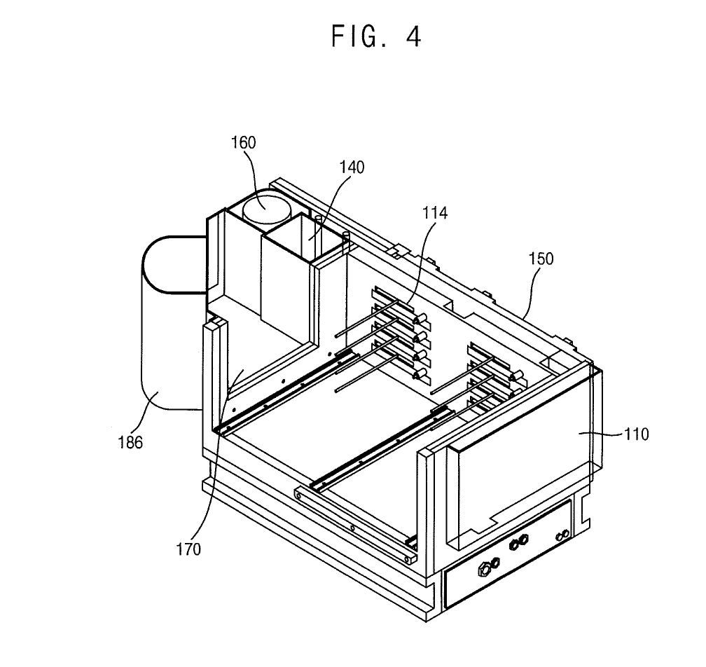

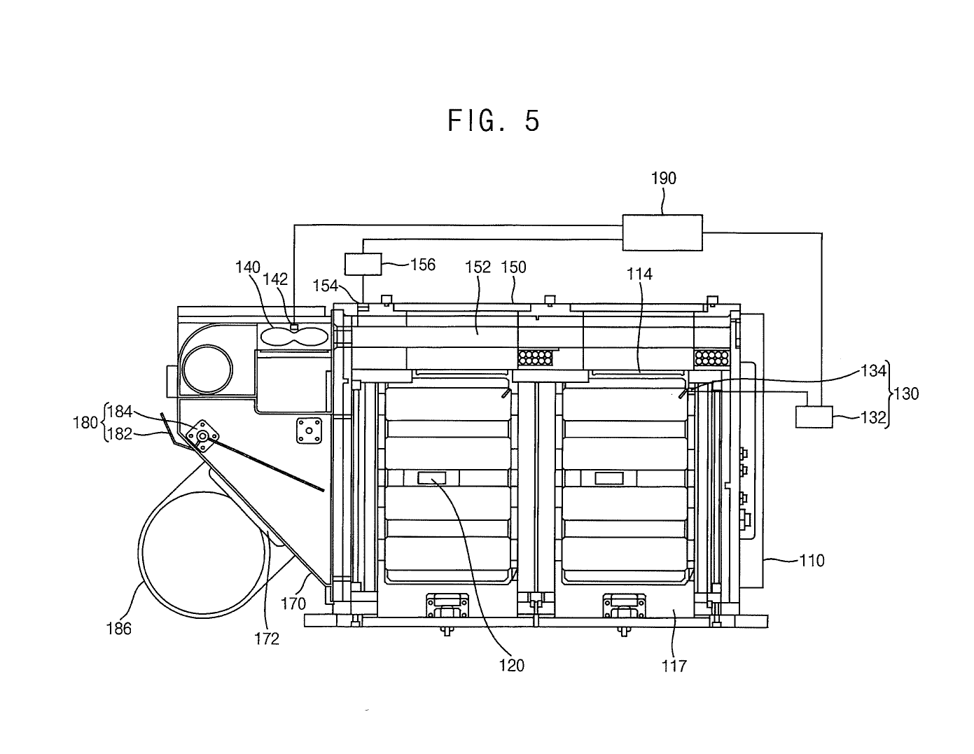

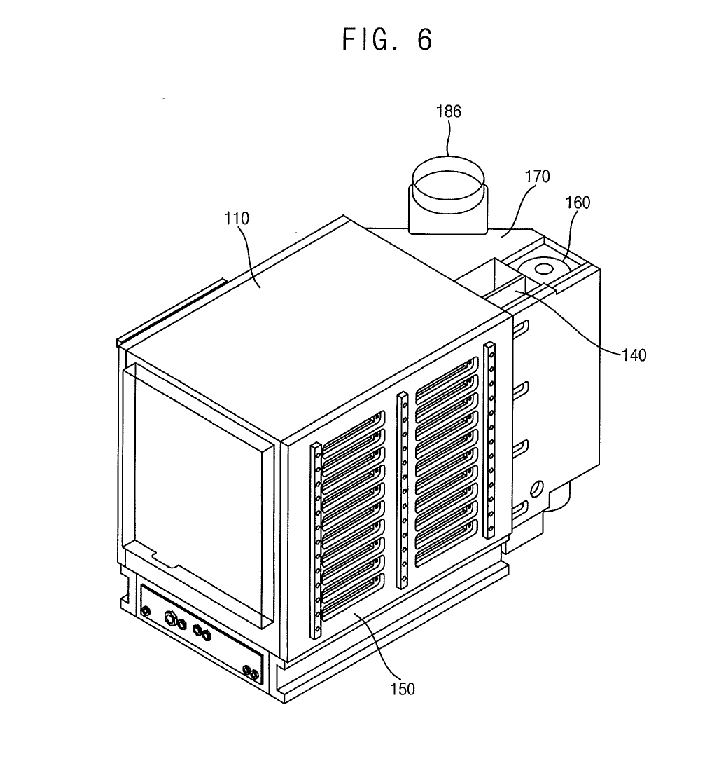

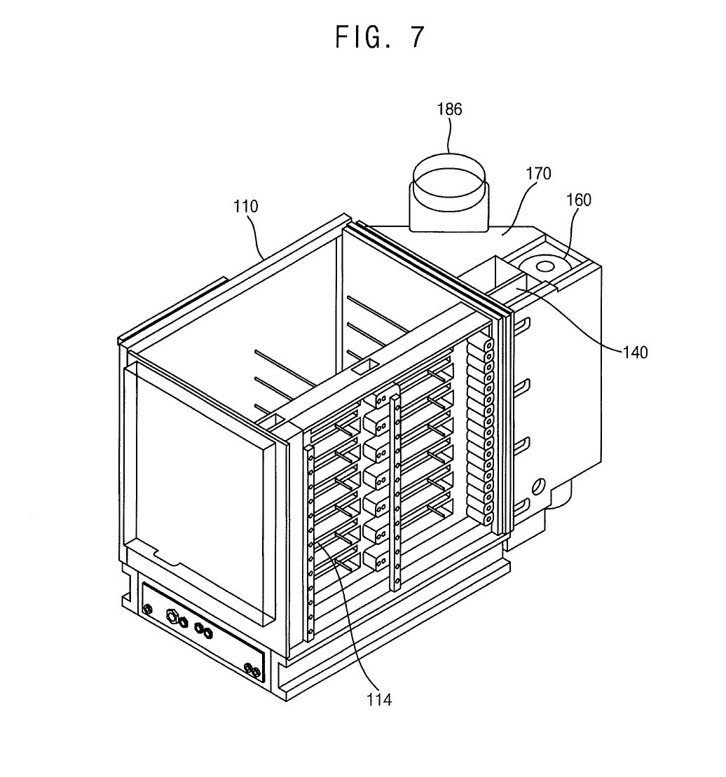

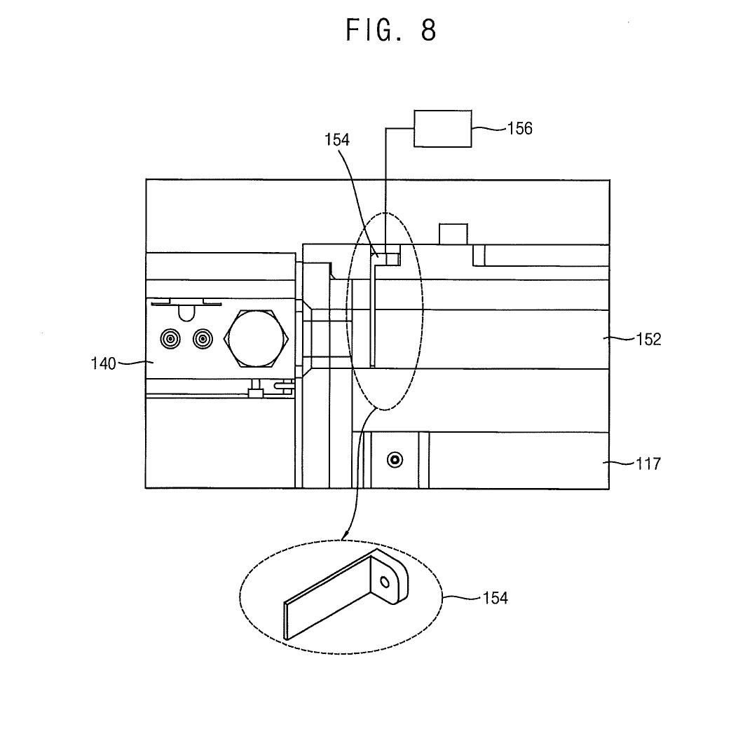

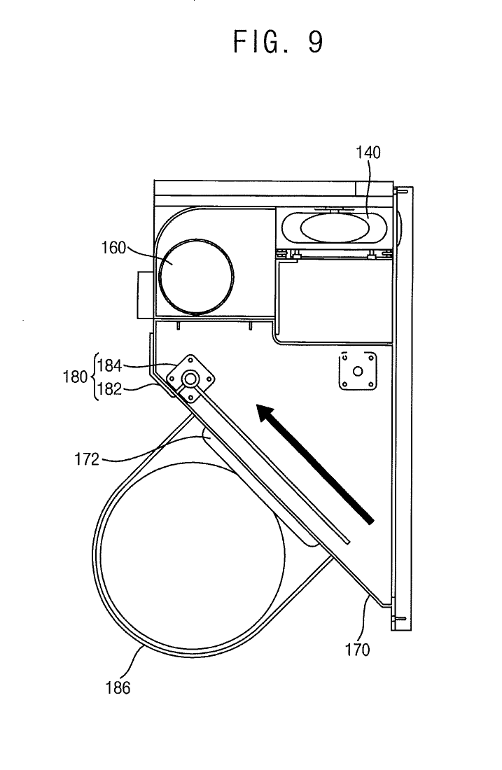

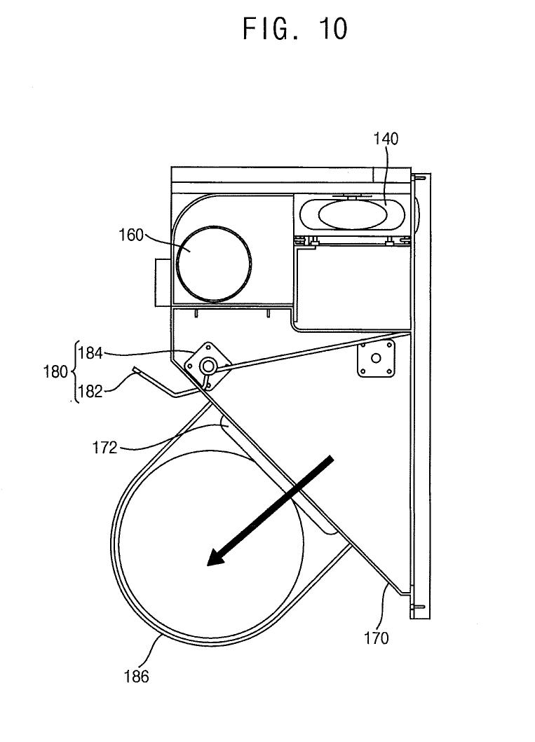

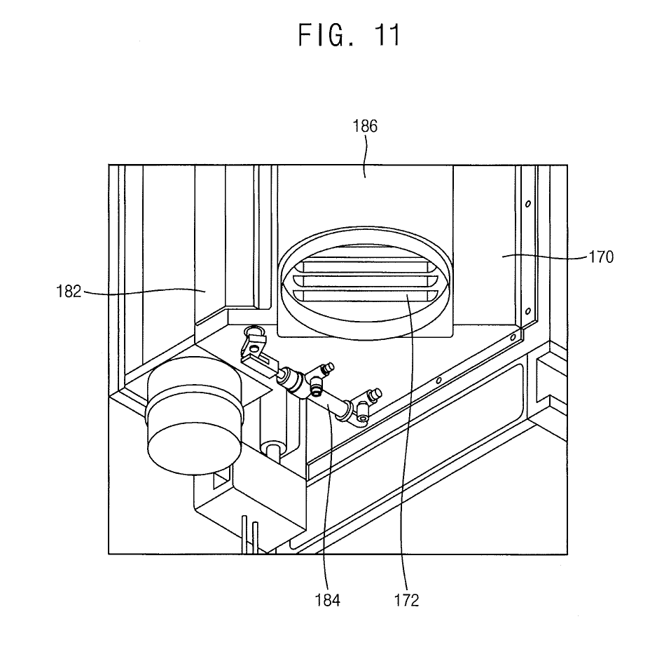

FIG. 1 is a perspective view illustrating an exemplary embodiment of an apparatus for testing electronic devices in accordance with principles of inventive concepts, FIG. 2 is an exploded perspective view illustrating a front side of a test chamber in the apparatus of FIG. 1, FIGS. 3 and 4 are perspective views illustrating a structure in the test chamber in FIG. 2, FIG. 5 is a cross-sectional view illustrating a heating unit and a cooling unit in the test chamber of FIG. 2, FIG. 6 is a perspective view illustrating a rear side of the test chamber in FIG. 2, FIG. 7 is a perspective view illustrating a structure in the test chamber of FIG. 6, FIG. 8 is an enlarged cross-sectional view illustrating a heating shutter of the test chamber in FIG. 7, FIGS. 9 and 10 are cross-sectional views illustrating operations of a circulation duct in FIG. 2, and FIG. 11 is an enlarged perspective view illustrating an exhausting member in FIG. 9.

Referring to FIGS. 1 to 4, an exemplary embodiment of an apparatus 100 for testing electronic devices in accordance with principles of inventive concepts may include a test chamber 110, a heating unit, a cooling unit 130 and a controller 190.

In exemplary embodiments, the test apparatus 100 may test the electronic devices at a uniform temperature. The electronic devices may include solid state drives (SSD), for example. Each of the electronic devices, such as SSDs, may include a temperature sensor.

The test chamber 110 may have a parallelepiped shape having an opening on the front side. Heating openings 114 may be formed at a rear side of the test chamber 110. Heat may be introduced into the test chamber 110 through the heating openings 114. The heating openings 114 may be arranged parallel to each other in a vertical direction.

A rack 115 may enter through the front side of the test chamber 110. The rack 115 may have a plurality of slots 117. The slots 117 may be formed in the rack 115 at substantially the same interval in a horizontal direction, for example. Each of the slots 117 may have an opened front and an opened rear. The opened rears of the slots 117 may be in fluidic communication with the heating openings 114, respectively. Thus, in exemplary embodiments, sizes and arrangements of the heating openings 114 in the test chamber 110 may vary in accordance with sizes and arrangement of the slots 117 of the rack 115, to operate in cooperation therewith.

A plurality of holders 119 configured to receive electronic devices to be tested may be inserted into the slots 117. The holders 119 in the slots 117 may be configured to close the opened fronts of the slots 117.

In exemplary embodiments, the test chamber 110 may be configured to receive the rack 115 having the slots 117. Alternatively, the slots 117 may be directly formed in test chamber 110 without the rack 115.

The heating unit may individually heat the electronic devices in the slots 117 under control of controller 190 configured to provide the each of the electronic devices with a uniform test temperature. The cooling unit 130 may individually cool the electronic devices in the slots 117 under control of controller 190 to provide each of the electronic devices with a uniform test temperature. The controller 190 may measure internal temperatures of the slots 117 to selectively control the heating unit and the cooling unit 130 in accordance with the measured temperatures. In accordance with principles of inventive concepts, temperature sensors 120 for measuring the internal temperatures of the slots 117 may be arranged in the slots 117. The temperature sensors 120 may measure the internal temperatures of central portions in the slots 117, for example. However, in exemplary embodiments in accordance with principle of inventive concepts, electronic devices to be tested, such as SSDs may include temperature sensors and, in which case, the controller 190 may receive information from the temperature sensors in the electronic devices to be tested, such as SSDs. In such exemplary embodiments additional temperature sensors 120 may not be included within slots 117.

Referring to FIGS. 5 to 8, the heating unit may include a heater 140 and a heating block 150. The heater 140 may be arranged in close proximity to the rear side of the test chamber 110. The heating block 150 may be arranged at the rear side of the test chamber 110.

The heating block 150 may include a plurality of heating passageways 152 which may be connected between the heater 140 and each of the heating openings 114. Heating shutters 154 may be arranged in the heating passageways 152 to selectively close/open the heating passageways 152. An actuator 156 may be configured to rotate the heating shutters 154 to open/close the heating passageways 152. The actuator 165 may be controlled by the controller 190. Thus, the heat generated from the heater 140 may be selectively supplied to the slots 117 through the opened heating passageways 152 and the heating openings 114. This heat transfer path may function to individually control the test temperatures of the electronic devices in the slots 117. In exemplary embodiments in accordance with principles of inventive concepts, heating shutters 154 may be opened or closed to different degrees in addition to being fully opened or fully closed and may be opened or closed in a continuously-variable manner in order to allow controller 190 to precisely and independently adjust the temperature within each slot 117.

A fan 160 may be arranged at a rear of the heater 140. The fan 160 may forcibly blow the heat generated from the heater 140 into the slots 117 through the heating passageways 152. In order to avoid over-heating, a safety sensor 142 configured to forcibly stop the heater 140 may be attached to the heater 140, for example.

A circulation duct 170 may be connected between each of the slots 117 and the fan 160. The circulation duct 170 may connect the slots 117 with the fan 160 to transfer the heat in the slots 117 to the heater 140 through the fan 160. Therefore, the heat circulated through the circulation duct 170 as well as the heat generated from the heater 140 may be supplied to the slots 117. In this manner, in accordance with principles of inventive concepts, the internal temperatures of the slots 117 may be rapidly increased to the test temperature and, as a result, time for testing the electronic devices may be substantially reduced.

The cooling unit 130 may include a chiller 132 and nozzles 134. The chiller 132 may generate cooling air for cooling the slots 117. Each of the nozzles 134 may be arranged in each of the slots 117. However, the number of the nozzle 134 arranged in the single slot 117 may not be restricted within a specific number. Additionally, each nozzle 134 may be oriented toward the central portion of an associated slot 117. Thus, the nozzles 134 may selectively inject the cooling air generated from the chiller 132 into the central portion of a slot 117, under control of controller 190. In this manner, in accordance with principles of inventive concepts, the cooling unit 130 may individually control the internal temperatures of each of the slots 117. In addition to provide precise, individual control, because the cooling air injected from the nozzles 134 in the slots 117 may individually decrease the internal temperatures of each of the slots 117, in accordance with principles of inventive concepts, this configuration may provide improved cooling efficiency compared to a cooling configuration where the slots 117 may be cooled en masse, using only one nozzle, for example.

In exemplary embodiments, when the controller 190 detects an internal temperature of the slot 117 that is higher than a targeted test temperature, the controller 190 may operate the heating shutter 154 in the heating passageway 152 connected to the slot 117, closing, or partially closing, the heating passageway 152 to shut the heat transfer to the slot 117. Additionally, controller 190 may operate the nozzle 134 in the slot 117 to inject cooling air from the nozzle 134 to decrease the internal temperature of the slot 117 in order to further accelerate adjustment of the internal temperature to the targeted test temperature. When the internal temperatures of all of the slots 117 exceed a targeted test temperature, the controller 190 may stop the heater 140 and operate all of the nozzles 134 to provide cooling air to all of the slots in order to accelerate cooling to reach the targeted test temperature.

In exemplary embodiments, heat may be exhausted from the slots in order to cool the slots efficiently. For example, if the slots contain heated air and the slots are to be cooled for testing electronic devices at reduced temperatures, residual heat may extend the period required to cool the slots for testing; exhausting heated air within the slots may reduce the time and energy required to cool the slots in such a situation and an apparatus in accordance with principle of inventive concepts includes an exhaust vent by which heated or cooled air within slots 117 may be circulated to an external environment in order to accelerate the process of cooling or heating, respectively, the internal environment of a slot 117. Referring to FIGS. 9 to 11, the circulation duct 170 may include an exhaust vent 172. An exhausting member 180 may selectively open/close the exhaust vent 172. The exhausting member 180 may include an exhausting shutter 182 and an actuator 184, for example. The exhausting shutter 182 may be rotatably connected to the circulation duct 170 to selectively open/close the exhaust vent 172. The actuator 184 may be configured to rotate the exhaust shutter 182 under control of controller 190. An exhaust hood through which air (or other gas within slots 117 which may be heated or cooled), may be exhausted may be connected to the exhaust vent 172.

Hereinafter, exemplary operations for individually providing one or more electronic devices with the test temperature by the test apparatus 100 in accordance with principles of inventive concepts may be illustrated in detail.

Rack 115 in which the electronic devices may be received may enter the test chamber 110 and all of the heating shutters 154 may be open to the heating passageways 152 and exhausting shutter 182 may close the exhaust vent 172 to begin a test operation in accordance with principles of inventive concepts.

The controller 190 may operate the heater 140 and heat generated from the heater 140 may be transferred into the slots 117 through the heating passageways 152 by the fan 160. The heat may be circulated through the slots 117 through the circulation duct 170 by the fan 160. Thus, heat originating in the slots 117 (generated, for example, by electronic devices being tested), as well as the heat generated from the heater 140, may be supplied/recirculated to the slots 117 so that the internal temperature in the slots 117 may be rapidly increased to a targeted test temperature.

The temperature sensors 120 in the slots 117 may individually measure the internal temperatures of each of the slots 117. In exemplary embodiments in which the electronic devices may include temperature sensors, such as temperature sensors in SSDs, the temperature sensors in the electronic devices may measure the internal temperatures of the slots 117 and those temperature sensors may be employed by an apparatus in accordance with principles of inventive concepts to control temperatures. When the internal temperatures of the slots 117 approach a targeted test temperature, the controller 190 may stop the heater 140, for example.

A test may be performed on the electronic devices at this targeted test temperature. During the test, any one of the electronic devices in any one of the slots 117 may generate sufficient heat to raise its temperature higher than that of other electronic devices, and of the targeted test temperature. The controller 190 may operate the corresponding heating shutter 154 to close the corresponding heating passageway 152 connected to the slot 117 of an electronic device that has exceeded the targeted test temperature. Thus, the heat may not be supplied to the corresponding slot 117, so that the internal temperature of the slot 117 may be reduced to the level of the targeted test temperature, although heat may be still be generated the electronic device under test.

In accordance with principles of inventive concepts, if closing the heating shutter 154 is not sufficient to reduce the temperature within slot 117 of interest, the controller 190 may operate the actuator 184 and exhausting shutter 182 may open the exhaust vent 172. In this manner, the heat in the slot 117 may be exhausted to the outside through the exhaust vent 172, not circulated through the circulation duct 170 and the internal temperature of the slot 117 may be rapidly decreased by exhausting the heat, also referred to herein as heat emission.

When heat emission, that is, exhausting heat through exhaust vent 172, is insufficient for reducing heat, the controller 190 may operate the chiller 132 to inject cooling air into the slot 117 from the nozzle 134 to forcibly decrease the internal temperature of the slot 117.

In accordance with principles of inventive concepts, forced cooling system using the cooling unit 130 may rapidly decrease the internal temperature of the slot 117. Particularly, when the heat emission and the forced cooling system may be simultaneously performed, the internal temperature of the slot 117 may be more rapidly decreased and, in exemplary embodiments, the controller 190 may simultaneously operate the cooling unit 130 and the exhausting member 180 to rapidly reduce the internal temperature of one or more slots 117.

In exemplary embodiments, the heating unit may individually control the internal temperatures of the slots 117. Alternatively, the heating unit may simultaneously control the internal temperatures of all the slots 117. In exemplary embodiments in accordance with principles of inventive concepts, individual control of cooling, through nozzles 134, may be employed, even if individual control of heating slots is not employed. That is, because excess heat typically occurs in only one or a limited number of devices being tested, an apparatus in accordance with principles of inventive concepts may supply heat to an entire rack of slots 117, using only one control (for example, opening or closing all shutters 154, as opposed to opening or closing them individually) and address overheating in a limited number of slots 117 by supplying cooling air, under individual control, to those slots that require it.

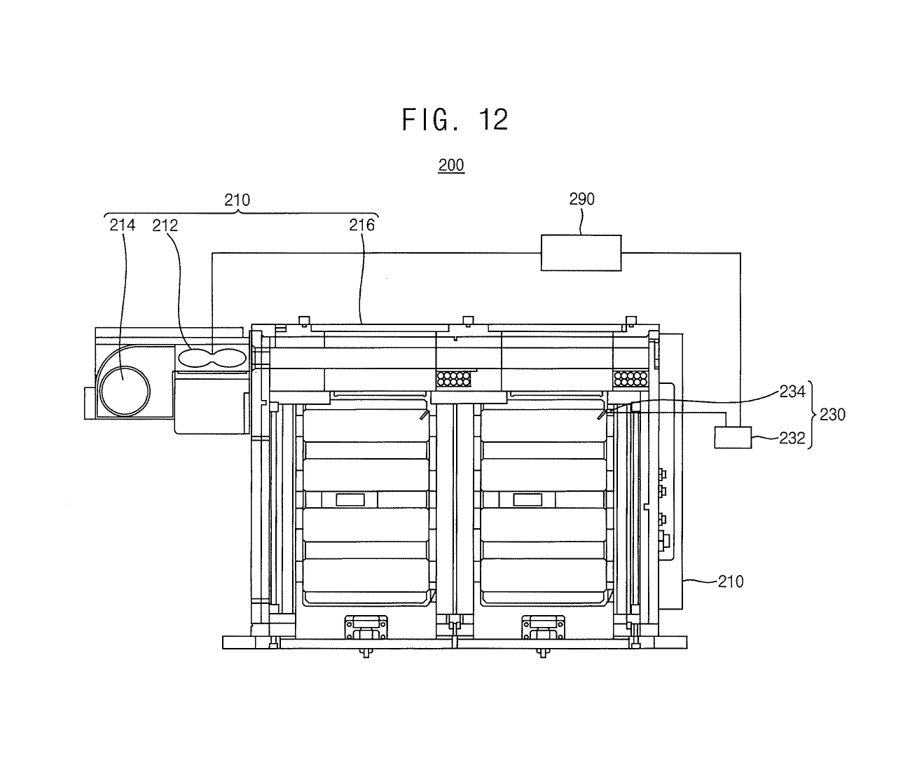

FIG. 12 is a cross-sectional view illustrating an apparatus for testing electronic devices in accordance with exemplary embodiments.

Referring to FIG. 12, an apparatus 200 for testing electronic devices in accordance with this exemplary embodiment may include a test chamber 210, a heating unit 210, a cooling unit 230 and a controller 290.

In exemplary embodiments, the test chamber 210 may have a structure substantially the same as the structure of the test chamber 110 in FIG. 1 and, for the sake of clarity and brevity, a detailed description of the same or similar elements will not be repeated here.

The heating unit 210 may include a heater 212, a fan 214 and a heating block 216. In exemplary embodiments, the heater 212 and the fan 214 may have functions substantially the same as the functions of the heater 140 and the fan 160 in FIG. 5. Thus, any further illustrations with respect to the test chamber 210 may be omitted herein for brevity. Further, the heating block 216 may have a structure substantially the same as the structure of the heating block 150 in FIGS. 6 and 7. Thus, any further illustrations with respect to the heating block 216 may be omitted herein for brevity. In this exemplary embodiment, however, the heating unit 210 may not include circulation duct 170 and exhausting member 180 of FIG. 5.

The cooling unit 230 may have elements substantially the same as those of the cooling unit 130 in FIG. 5. Thus, any further illustrations with respect to the cooling unit 230 may be omitted herein for brevity.

The controller 290 may selectively control the heating unit 210 and the cooling unit 230 in accordance with the internal temperatures of the slots 117.

According to exemplary embodiments, the heating unit and/or the cooling unit may individually heat and/or cool electronic devices in test slots 117 so that temperatures of the electronic devices may be individually controlled. Thus, the electronic devices may be provided with a uniform test temperature so that the reliability of test results may be improved. Additionally, in embodiments that include a circulation duct, the circulation duct of the heating unit may rapidly provide the test temperature to the electronic devices. Furthermore, the nozzles within individual slots that supply cooling air may individually cool each of the slots so that the efficiency of cooling the slots may be improved. As a result, the time required to test electronic devices may be substantially reduced. In exemplary embodiments in which an electronic device to be tested includes a temperature sensor, such as an SSD that includes a temperature sensor, an apparatus in accordance with principles of inventive concepts may employ the temperature sensors of the SSDs, rather than employing additional temperature sensors within slots 117, thereby reducing test system expenses.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of inventive concepts. Accordingly, all such modifications are intended to be included within the scope of inventive concepts as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. An apparatus for testing electronic devices, the apparatus comprising:
a test chamber including a plurality of slots, the slots configured to receive the electronic devices;
a heating unit configured to heat the electronic devices in the slots;
a cooling unit configured to individually cool the electronic devices in each of the slots; and
a controller configured to control the heating unit and the cooling unit according to internal temperatures of each of the slots.

2. The apparatus of claim 1, wherein the controller comprises a temperature sensor arranged in each of the slots to individually measure the internal temperatures of the slots.

3. The apparatus of claim 1, wherein the electronic devices comprise solid state drives (SSDs), each of the SSDs comprises a temperature sensor, and the controller selectively controls the heating unit and the cooling unit according to the internal temperatures of each of the slots measured by the temperature sensors in the SSDs.

4. The apparatus of claim 1, wherein the heating unit individually heats the electronic devices in the slots.

5. The apparatus of claim 4, wherein the heating unit comprises:
a heater configured to heat;
a heating block having heating passageways, the heating passageways configured to individually connect the heat provided by the heater with the slots; and
heating shutters configured to selectively open/close the heating passageways under control of the controller.

6. The apparatus of claim 5, wherein the heating unit further comprises a circulation duct connected between the heater and the slots to circulate the heat between the slots and the heater.

7. The apparatus of claim 6, wherein the circulation duct comprises an exhaust vent configured to exhaust heat to an environment external to the apparatus, and the heating unit further comprises an exhausting member configured to selectively open/close the exhaust vent under control of the controller.

8. The apparatus of claim 7, wherein the exhausting member comprises:
an exhausting shutter configured to selectively open/close the exhaust vent; and
an actuator configured to operate the exhausting shutter under control of the controller.

9. The apparatus of claim 8, wherein the exhausting member further comprises an exhaust hood connected to the exhaust vent.

10. The apparatus of claim 6, wherein the heating unit further comprises a fan arranged between the circulation duct and the heater to circulate the heat.

11. The apparatus of claim 5, wherein the heating unit further comprises a safety sensor configured to selectively stop the heater under control of the controller.

12. The apparatus of claim 1, wherein the cooling unit comprises:
a chiller configured to generate cooling air; and
a nozzle arranged in each of the slots to inject the cooling air into the slots.

13. An apparatus for testing solid state drives (SSDs) each of which includes a temperature sensor, the apparatus comprising:
a test chamber including a plurality of slots, the slots configured to receive the SSDs;
a heating unit configured to individually heat the SSDs in the slots;
a cooling unit configured to individually cool the SSDs in the slots; and
a controller configured to control the heating unit and the cooling unit according to internal temperatures of each of the slots measured by the temperature sensors.

14. The apparatus of claim 13, wherein the heating unit comprises:
a heater configured to heat;
a heating block having heating passageways, the heating passageways configured to individually connect the heat with the slots;
heating shutters configured to selectively open/close the heating passageways under control of the controller;
a circulation duct connected between the heater and the slots to circulate the heat between the slots and the heater, the circulation duct having an exhaust vent configured to exhaust the heat to an environment outside the apparatus;
a fan arranged between the circulation duct and the heater to circulate the heat; and
an exhausting member configured to selectively open/close the exhaust vent.

15. The apparatus of claim 13, wherein the cooling unit comprises:
a chiller configured to generate cooling air; and
a nozzle arranged in each of the slots to inject the cooling air into the slots.

16. An apparatus for testing electronic devices, the apparatus comprising:
a test chamber for receiving a rack;
a rack including a plurality of slots, the slots configured to receive the electronic devices;
a heating unit configured to heat the electronic devices in the slots;
a cooling unit configured to individually cool the electronic devices in each of the slots; and
a controller configured to control the heating unit and the cooling unit according to internal temperatures of each of the slots.

17. The apparatus of claim 16, wherein the controller is configured to control the heating and cooling units in response to temperatures measured by sensors included on electronic devices being tested.

18. The apparatus of claim 17, wherein the controller is configured to control the heating and cooling units wherein the electronic devices being tested are solid state drives.

19. The apparatus of claim 18, wherein the heating unit comprises:
a heater configured to heat;
a heating block having heating passageways, the heating passageways configured to individually connect the heat with the slots;
heating shutters configured to selectively open/close the heating passageways under control of the controller;
a circulation duct connected between the heater and the slots to circulate the heat between the slots and the heater, the circulation duct having an exhaust vent configured to exhaust the heat to an environment the outside the apparatus;
a fan arranged between the circulation duct and the heater to circulate the heat; and
an exhausting member configured to selectively open/close the exhaust vent.

20. The apparatus of claim 18, wherein the cooling unit comprises:
a chiller configured to generate cooling air; and
a nozzle arranged in each of the slots to inject the cooling air into the slots.
